(19) United States
(12) Patent Application Publication
(10) Pub. No.: US 2024/0113666 A1
(43) Pub. Date: Apr. 4, 2024

(54) AMPLIFIER MODULE

(71) Applicant: Murata Manufacturing Co., Ltd., Kyoto (JP)

(72) Inventor: Kenichi SHIMAMOTO, Kyoto (JP)

(21) Appl. No.: 18/477,992

(22) Filed: Sep. 29, 2023

(30) Foreign Application Priority Data
Sep. 30, 2022 (JP) 2022-158484

(51) Int. Cl. H03F 1/56; H03F 3/21; H03F 3/45

(52) U.S. Cl. CPC H03F 1/56; H03F 3/211; H03F 3/45076; H03F 2200/09; H03F 2200/378; H03F 2200/451

(57) ABSTRACT

An amplifier module includes an input terminal; a first preamplifier formed in or on a first substrate and configured to amplify a signal that is input to the input terminal; a first postamplifier and a second postamplifier that are formed in or on a second substrate and that are configured to receive an output of the first preamplifier and output a differential signal; an output balun configured to receive the differential signal that is output from the first postamplifier and the second postamplifier; and a variable capacitance element. The output balun includes a primary winding subjected to the differential signal and a secondary winding, and the variable capacitance element is connected in parallel with the primary winding of the output balun.

### CROSS REFERENCE TO RELATED APPLICATION

This application claims priority from Japanese Patent Application No. 2022-158484 filed on Sep. 30, 2022. The content of this application is incorporated herein by reference in its entirety.

### BACKGROUND ART

The present disclosure relates to an amplifier module.

Amplifier modules used for power amplification, for example, in wireless communication are known (for example, refer to U.S. Patent Application Publication No. 2015/0349723). The amplifier module disclosed in U.S. Patent Application Publication No. 2015/0349723 includes a substrate for a preamplifier and another substrate for a postamplifier.

### BRIEF SUMMARY

To obtain desirable output characteristics of an amplifier module, proper adjustment of the impedance value of the amplifier module is suitable. The impedance value of the actual amplifier module differs from the impedance value estimated in the design stage in some cases. Thus, proper adjustment of the impedance value of the amplifier module is suitable.

The present disclosure provides an amplifier module that enables proper adjustment of the impedance value.

To address the above issue, an amplifier module according to an aspect of the present disclosure includes an input terminal; a first preamplifier formed in or on a first substrate and configured to amplify a signal that is input to the input terminal; a first postamplifier and a second postamplifier that are formed in or on a second substrate and that are configured to receive an output of the first preamplifier and output a differential signal; an output balun configured to receive the differential signal that is output from the first postamplifier and the second postamplifier; and a variable capacitance element. The output balun includes a primary winding subjected to the differential signal and a secondary winding, and the variable capacitance element is connected in parallel with the primary winding of the output balun.

According to the present disclosure, an amplifier module enables proper adjustment of the impedance.

### BRIEF DESCRIPTION OF THE DRAWINGS

FIG. 1 depicts an example of a differential amplification device according to a first embodiment of the present disclosure;

FIG. 2 depicts an example of a differential amplification device according to a second embodiment of the present disclosure;

FIG. 3 depicts an example of a differential amplification device according to a third embodiment of the present disclosure;

FIG. 4 depicts an example of a differential amplification device according to a fourth embodiment of the present disclosure;

FIG. 5 depicts an example of a differential amplification device according to a fifth embodiment of the present disclosure;

FIG. 6 depicts an example of a differential amplification device according to a sixth embodiment of the present disclosure;

FIG. 7 depicts an example of a differential amplification device according to a seventh embodiment of the present disclosure;

FIG. 8 depicts an example of a differential amplification device according to an eighth embodiment of the present disclosure;

FIG. 9 depicts an example of a differential amplification device according to a ninth embodiment of the present disclosure;

FIG. 10 depicts an example of a differential amplification device according to a tenth embodiment of the present disclosure;

FIG. 11 illustrates an effect of capacitance value adjustment;

FIG. 12 is a Smith chart illustrating a relationship between impedance adjustment and current consumption; and

FIG. 13 depicts an example of the layout of an amplifier module.

### DETAILED DESCRIPTION

Hereinafter, embodiments of the present disclosure will be described in detail with reference to the drawings. In the following description of each embodiment, if an element or a portion is the same as or similar to an element or a portion in another embodiment, those elements or portions are denoted by the same symbol, and redundant description of those elements or portions is simplified or omitted. It is to be noted that the present disclosure is not limited to the embodiments. Elements described in each embodiment encompass replacements that are easily conceivable to one having ordinary skill in the art or something that is substantially equivalent. Configurations described below may appropriately be combined with each other. Further, configurations may be omitted, replaced, or changed within the spirit of the disclosure.

### First Embodiment

### Configuration

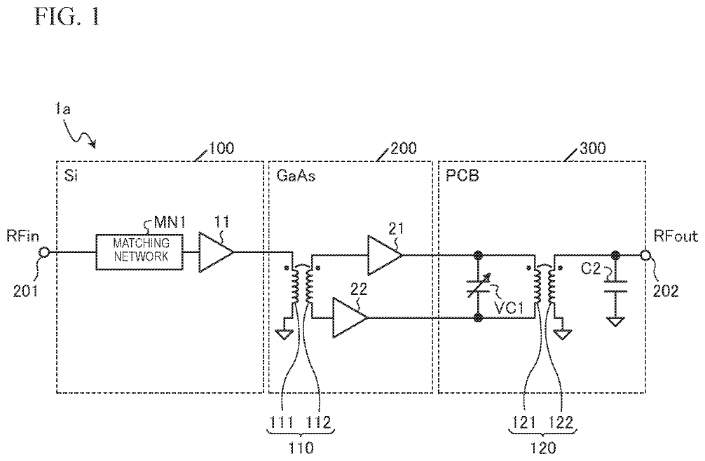

FIG. 1 depicts an example of an amplifier module according to a first embodiment of the present disclosure. An amplifier module 1a depicted in FIG. 1 includes an input terminal 201, a matching network MN1, a first preamplifier 11, inductors 111 and 112, a first postamplifier 21, a second postamplifier 22, a variable capacitor VC1, inductors 121 and 122, a capacitor C2, and an output terminal 202.

The first preamplifier 11 is a driver-stage amplifier configured to amplify a signal that is input to the input terminal. The first and second postamplifiers 21 and 22 are power-stage amplifiers configured to amplify a signal amplified by the driver-stage amplifier. The first and second postamplifiers 21 and 22 form a differential amplification circuit. The first and second postamplifiers 21 and 22 are configured to output a differential signal.

The inductors 111 and 112 are configured to be electromagnetically coupled to each other and form a transformer 110. Specifically, the inductor 111 is the primary winding, and the inductor 112 is the secondary winding in the transformer 110. One end of the inductor 111 is connected to the input terminal 201, and the other end is connected to the reference potential. Non-limiting example of the reference potential is the ground potential in the present disclosure. The same applies to the description hereinafter. One end of the inductor 112 is connected to the input of the amplifier 21, and the other end of the inductor 112 is connected to the input of the amplifier 22. The transformer 110 operates as an input balun configured to perform unbalanced-balanced conversion on a signal in the inductor 111, which is the primary winding. A signal that is input to the inductor 111 is converted by the transformer 110, and a differential signal is generated in the inductor 112. Electromagnetic-field coupling is defined as either magnetic-field coupling, electric-field coupling, or a combination of both.

The inductors 121 and 122 are configured to be electromagnetically coupled to each other and form a transformer 120. Specifically, the inductor 121 is the primary winding, and the inductor 122 is the secondary winding in the transformer 120. One end of the inductor 122 is connected to the output terminal 202. The other end of the inductor 122 is connected to the reference potential. The transformer 120 operates as an output balun configured to perform balanced-unbalanced conversion. The transformer 120 is configured to convert a differential signal applied to the primary winding into a single-ended signal. The single-ended signal after conversion is output from the output terminal 202. A matching network, a band select switch, duplexers, and an antenna select switch, which are not depicted, are disposed in the stages subsequent to the output terminal 202.

The variable capacitor VC1, which is a variable capacitance element, is connected in parallel with the inductor 121, which is the primary winding of the output balun. One end of the capacitor C2 is connected to one end of the inductor 122. The other end of the capacitor C2 is connected to the reference potential. The variable capacitor VC1 may include, for example, multiple capacitors, and a connection to a single capacitor or a connection to multiple capacitors may be selected in response to a control signal from a controller not depicted.

Among the components of the amplifier module 1a depicted in FIG. 1, the matching network MN1 and the first preamplifier 11 are disposed in or on a silicon substrate 100, which is a first substrate. Among the components of the amplifier module 1a, the transformer 110, the first postamplifier 21, and the second postamplifier 22 are disposed in or on a gallium arsenide substrate 200, which is a second substrate. Among the components of the amplifier module 1a, the variable capacitor VC1, the transformer 120, and the capacitor C2 are disposed in or on a printed circuit board (PCB), which is a third substrate. As described above, the first preamplifier 11, which corresponds to a driver stage, is disposed in or on the silicon substrate 100, which is the first substrate. The first postamplifier 21 and the second postamplifier 22, which correspond to a power stage, are disposed in or on the gallium arsenide substrate 200. The silicon substrate 100 and the gallium arsenide substrate 200 are each mounted on a printed circuit board using bumps or bonding wires.

### Operation

A signal that is input to the input terminal 201, for example, a radio frequency (RF) input signal RFin is input to the first preamplifier 11 via the matching network MN1. A signal amplified by the first preamplifier 11 is split via the transformer 110 into two signals having phases approximately 180° apart and is input to the first postamplifier 21 and the second postamplifier 22. A differential signal amplified by the first postamplifier 21 and the second postamplifier 22 is converted to a single-ended signal by the transformer 120. The single-ended signal after the conversion is output from the output terminal 202. Adjusting the capacitance value of the variable capacitor VC1 enables proper adjustment of the impedance value. Thus, desirable characteristics are obtained for the signal that is output from the output terminal 202.

Changing the capacitance of the variable capacitor VC1 enables impedance adjustment. In particular, a deviation from the preplanned design value of impedance may be corrected, and proper adjustment of the impedance value may be achieved. The proper adjustment of the impedance value enables desirable characteristics to be obtained for the signal that is output from the output terminal 202.

### Second Embodiment

### Configuration

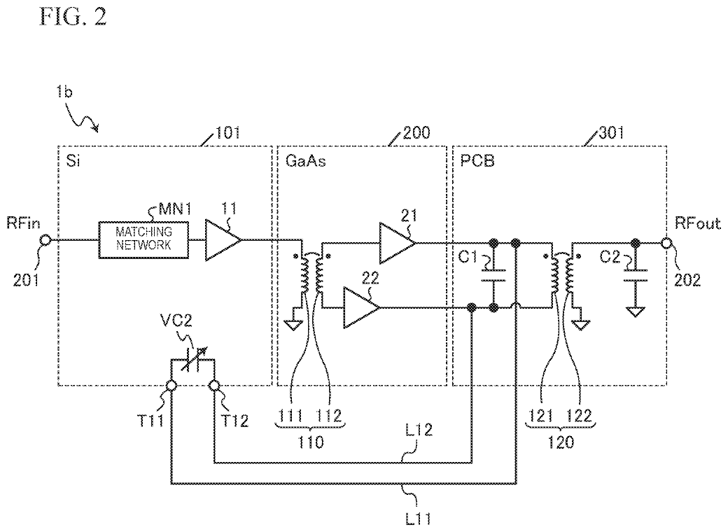

FIG. 2 depicts an example of an amplifier module according to a second embodiment of the present disclosure. In contrast to the amplifier module 1a described with reference to FIG. 1, an amplifier module 1b depicted in FIG. 2 includes a capacitor C1 having a fixed capacitance value instead of the variable capacitor VC1. The capacitor C1 is connected in parallel with the inductor 121. The capacitor C1 is disposed in or on a printed circuit board 301 together with the transformer 120 and the capacitor C2.

In contrast to the amplifier module 1a, the amplifier module 1b also includes a variable capacitor VC2. The variable capacitor VC2 is disposed in or on a silicon (Si) substrate 101, which is a first substrate, together with the matching network MN1 and the first preamplifier 11. Thus, the variable capacitor VC2, which is a variable capacitance element, is disposed in or on a substrate that differs from a substrate where the transformer 120, which is the output balun, is disposed.

The capacitance value of the variable capacitor VC2 is allowed to vary in the range of the minimum value to the maximum value. The maximum value of the variable capacitor VC2 is desirably less than the capacitance value of the capacitor C1, which is a fixed capacitance element. In other words, the capacitance value of the capacitor C1 is more than the maximum value of the variable capacitor VC2.

The capacitance values are desirably chosen so that a large portion of the compound capacitance formed of the capacitor C1 and the variable capacitor VC2 is provided by the capacitor C1 and the remaining portion is provided by the variable capacitor VC2. Selecting the capacitance values in this way enables minute adjustment to a relatively large capacitance value of the capacitor C1 by using the capacitance value of the variable capacitor VC2. A variable capacitor configured to cover all the capacitance range may lead to a large size of the element. In contrast, a configuration for minutely adjusting a large capacitance value of the capacitor C1 by using the capacitance value of the variable capacitor VC2 may reduce an increase in the size of the element. The variable capacitor VC2 disposed in or on the silicon (Si) substrate 101 achieves a more precisely designed variation mechanism than the variable capacitor VC2 disposed in or on the gallium arsenide substrate 200 or the printed circuit board 300.

One end of the capacitor C1 is electrically connected to a terminal T11 of the silicon (Si) substrate 101 using a wire trace L11. The other end of the capacitor C1 is electrically connected to a terminal T12 of the silicon (Si) substrate 101 using a wire trace L12. Thus, the variable capacitor VC2 is connected in parallel with the capacitor C1. Other configurations of the amplifier module 1b are the same as or similar to those of the amplifier module 1a described with reference to FIG. 1. The wire traces L11 and L12 each has an inductance value. The impedance may be adjusted not solely with the variable capacitor VC2 but with an LC circuit including the wire traces L11 and L12 in addition to the variable capacitor VC2. In particular, the way of routing the wire traces L11 and L12 may be changed on the printed circuit board 300, and the actual impedance value obtained after mounting may be made closer to the design value if the silicon substrate 101 and the gallium arsenide substrate 200 mounted in or on the printed circuit board 300 causes a deviation in the impedance value from the design value.

The wire traces L11 and L12 are desirably formed of conductor traces disposed in or on a printed circuit board instead of bonding wires. Bonding wires have a large variation in the wire length, leading to a large variation in the inductance value. In contrast, conductor traces disposed in or on a printed circuit board achieve a smaller variation in length, thickness and width and have a smaller variation in the inductance value.

### Operation

The wire traces L11 and L12 each has an inductance value. The inductance value of each of the wire traces L11 and L12 may be adjusted by the adjustment of the length, the thickness, and the width of each wire trace. Thus, the impedance may be adjusted with the wire trace L11, the variable capacitor VC2, and the wire trace L12, which are connected in series, and further the capacitor C1, which is connected in parallel with the wire traces L11 and L12 and the variable capacitor VC2. In summary, the impedance may be adjusted not solely with the variable capacitor VC2 but with the LC circuit including the wire traces L11 and L12 in addition to the variable capacitor VC2. The amplifier module 1a according to the first embodiment described above is configured to perform adjustment using a single variable capacitor, the variable capacitor VC1. In contrast, more proper adjustment of the impedance is possible in the present embodiment because the adjustment is performed with the variable capacitor VC2, the wire traces L11 and L12, and further the capacitor C1, which is connected in parallel with the variable capacitor VC2 and the wire traces L11 and L12.

### Third Embodiment

### Configuration

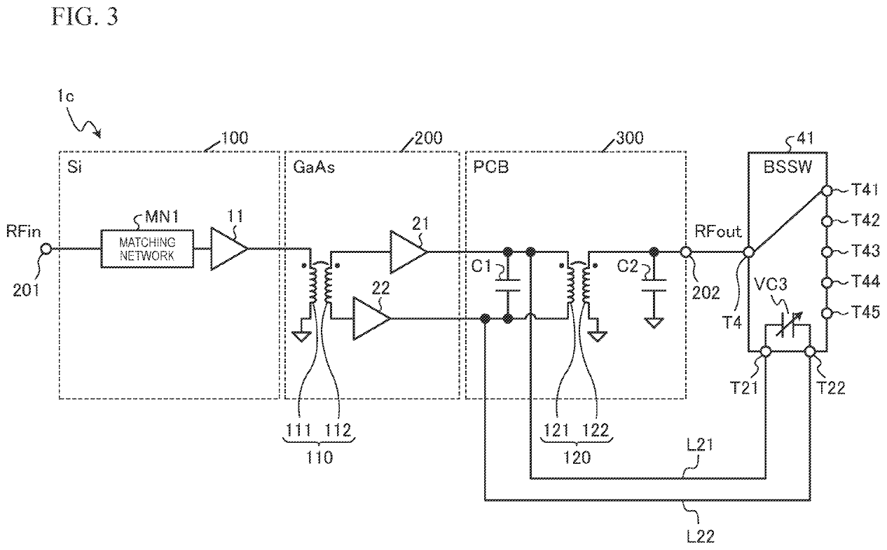

FIG. 3 depicts an example of an amplifier module according to a third embodiment of the present disclosure. In contrast to the amplifier module 1a described with reference to FIG. 1, an amplifier module 1c depicted in FIG. 3 includes a capacitor C1 having a fixed capacitance value instead of the variable capacitor VC1. The capacitor C1 is connected in parallel with the inductor 121. The capacitor C1 is disposed in or on the printed circuit board 300 together with the transformer 120 and the capacitor C2.

In contrast to the amplifier module 1a, the amplifier module 1c also includes a variable capacitor VC3. The variable capacitor VC3 is connected in parallel with the capacitor C1, which is a fixed capacitance element. The variable capacitor VC3 is disposed in or on a substrate where a band select switch (BSSW) 41 is mounted. In other words, the variable capacitor VC3 is disposed in or on the same substrate as a band select switch unit. The band select switch unit is disposed, for example, in or on a silicon (Si) substrate that differs from the silicon (Si) substrate 100. The variable capacitor VC3, which is a variable capacitance element, is disposed in or on a substrate that differs from a substrate where the transformer 120, which is the output balun, is disposed. The band select switch 41 is configured to connect a terminal T4 to one terminal selected from terminals T41, T42, T43, T44, and T45 in response to a control signal not depicted.

The capacitance value of the variable capacitor VC3, which is the variable capacitance element, is allowed to vary in the range of the minimum value to the maximum value. The maximum value of the variable capacitor VC3 is desirably less than the capacitance value of the capacitor C1, which is the fixed capacitance element. In other words, the capacitance value of the capacitor C1 is more than the maximum value of the variable capacitor VC3.

The capacitance values are desirably chosen so that a large portion of the compound capacitance formed of the capacitor C1 and the variable capacitor VC2 is provided by the capacitor C1 and the remaining portion is provided by the variable capacitor VC2. Selecting the capacitance values in this way enables minute adjustment to a relatively large capacitance value of the capacitor C1 by using the capacitance value of the variable capacitor VC3. A variable capacitor configured to cover all the capacitance range may lead to a large size of the element. In contrast, a configuration for minutely adjusting a large capacitance value of the capacitor C1 by using the capacitance value of the variable capacitor VC2 may reduce an increase in the size of the element. The variable capacitor VC3 disposed in or on the silicon (Si) substrate achieves a more precisely designed variation mechanism than the variable capacitor VC3 disposed in or on the gallium arsenide substrate 200 or the printed circuit board 300.

One end of the capacitor C1 is electrically connected to a terminal T21 of the band select switch 41 using a wire trace L21. The other end of the capacitor C1 is electrically connected to a terminal T22 of the band select switch 41 using a wire trace L22. Thus, the variable capacitor VC3 is connected in parallel with the capacitor C1. The variable capacitor VC3 is also connected in parallel with the inductor 121, which is the primary winding of the output balun. Other configurations in FIG. 3 are the same as or similar to those of the amplifier module 1a described with reference to FIG. 1. The wire traces L21 and L22 each has an inductance value. The impedance may be adjusted not solely with the variable capacitor VC3 but with an LC circuit including the wire traces L21 and L22 in addition to the variable capacitor VC3. In particular, the way of routing the wire traces L21 and L22 may be changed on the printed circuit board 300, and the actual impedance value obtained after mounting may be made closer to the design value if the silicon substrate 100 and the gallium arsenide substrate 200 mounted in or on the printed circuit board 300 causes a deviation in the impedance value from the design value.

### Operation

The wire traces L21 and L22 each has an inductance value. Thus, the impedance value may be adjusted with the wire trace L21, the variable capacitor VC3, and the wire trace L22, which are connected in series, and further the capacitor C1, which is connected in parallel with the wire traces L21 and L22 and the variable capacitor VC3. In summary, the impedance may more properly be adjusted not solely with the variable capacitor VC3 but with the LC circuit including the wire traces L21 and L22 in addition to the variable capacitor VC3.

### Fourth Embodiment

### Configuration

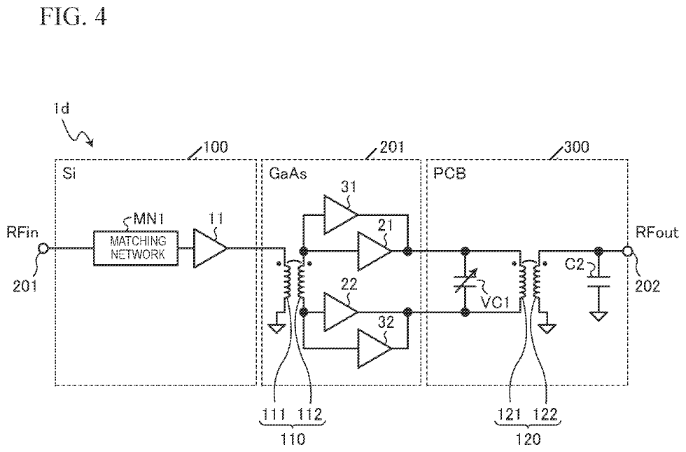

FIG. 4 depicts an example of an amplifier module according to a fourth embodiment of the present disclosure. An amplifier module 1d depicted in FIG. 4 has the same configuration as the amplifier module 1a described with reference to FIG. 1 except that a third postamplifier 31 and a fourth postamplifier 32 are added to the configuration. The third postamplifier 31 is connected in parallel with the first postamplifier 21. The fourth postamplifier 32 is connected in parallel with the second postamplifier 22. The third and fourth postamplifiers 31 and 32 form a differential amplification circuit.

### Operation

The amplifier module 1d has a low power mode and a high power mode as the operation modes having different output power. The high power mode has higher output power than the low power mode. In the low power mode, which is a first operation mode, the first and second postamplifiers 21 and 22 operate, and the third and fourth postamplifiers 31 and 32 do not operate. In the high power mode, which is a second operation mode, the first and second postamplifiers 21 and 22 operate, and the third and fourth postamplifiers 31 and 32 also operate. The total emitter size of the postamplifiers configured to operate in the second operation mode (the first postamplifier 21, the second postamplifier 22, the third postamplifier 31, and the fourth postamplifier 32) is set larger than the total emitter size of the postamplifiers configured to operate in the first operation mode (the first postamplifier 21 and the second postamplifier 22), and the low power mode and the high power mode are provided in this way. For example, the emitter sizes of the power transistors of the third postamplifier 31 and the fourth postamplifier 32 are larger than the emitter sizes of the power transistors of the first postamplifier 21 and the second postamplifier 22. The emitter sizes of the power transistors of the first postamplifier 21 and the second postamplifier 22 may be smaller than the emitter sizes of the power transistors of the third postamplifier 31 and the fourth postamplifier 32. Alternatively, the emitter sizes of the power transistors of the first postamplifier 21 and the second postamplifier 22 may be equal to the emitter sizes of the power transistors of the third postamplifier 31 and the fourth postamplifier 32.

As described above, the amplifier module 1d achieves two operation modes. In each of the two operation modes, adjusting the capacitance value of the variable capacitor VC1 enables proper setting of the impedance for each operation mode. For example, the capacitance value of the variable capacitor VC1 is set larger in the low power mode, and the capacitance value of the variable capacitor VC1 is set smaller in the high power mode. In other words, the capacitance value of the variable capacitor VC1 is adjusted so that the capacitance value in the low power mode is higher than the capacitance value in the high power mode.

### Fifth Embodiment

### Configuration

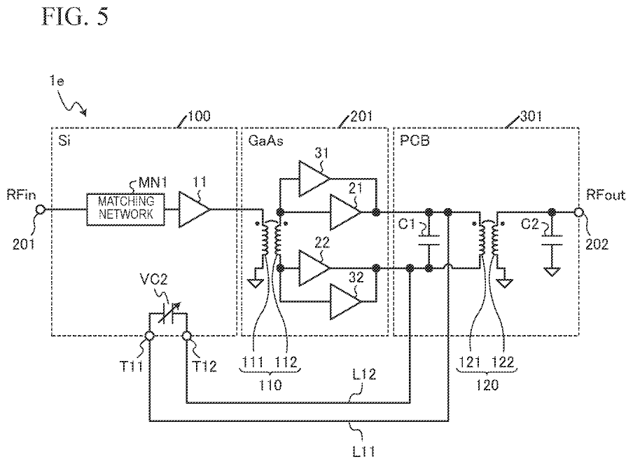

FIG. 5 depicts an example of an amplifier module according to a fifth embodiment of the present disclosure. An amplifier module 1e depicted in FIG. 5 has the same configuration as the amplifier module 1b described with reference to FIG. 2 except that the third postamplifier 31 and the fourth postamplifier 32 are added to the configuration. The third postamplifier 31 is connected in parallel with the first postamplifier 21. The fourth postamplifier 32 is connected in parallel with the second postamplifier 22. Other configurations of the amplifier module 1e are the same as or similar to those of the amplifier module 1b described with reference to FIG. 2.

### Operation

The amplifier module 1e has a low power mode and a high power mode as the operation modes having different output power. The high power mode has higher output power than the low power mode.

In the low power mode of the amplifier module 1e, the first and second postamplifiers 21 and 22 operate, and the third and fourth postamplifiers 31 and 32 do not operate. In the high power mode of the amplifier module 1e, the first and second postamplifiers 21 and 22 operate, and the third and fourth postamplifiers 31 and 32 also operate.

As described above, the amplifier module 1e achieves two operation modes. In each of the two operation modes, adjusting the capacitance value of the variable capacitor VC2 enables proper setting of the impedance for each operation mode. For example, the capacitance value of the variable capacitor VC2 is set larger in the low power mode, and the capacitance value of the variable capacitor VC2 is set smaller in the high power mode. In other words, the capacitance value of the variable capacitor VC2 is adjusted so that the capacitance value in the low power mode is higher than the capacitance value in the high power mode. In this case, the impedance may more properly be adjusted not solely with the variable capacitor VC2 but with an LC circuit including the wire traces L11 and L12 in addition to the variable capacitor VC2.

### Sixth Embodiment

### Configuration

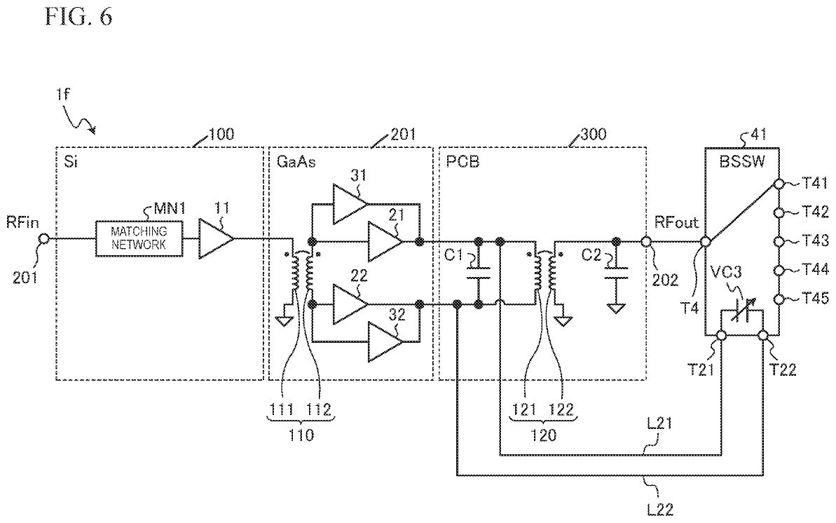

FIG. 6 depicts an example of an amplifier module according to a sixth embodiment of the present disclosure. An amplifier module 1f depicted in FIG. 6 has the same configuration as the amplifier module 1c described with reference to FIG. 3 except that the third postamplifier 31 and the fourth postamplifier 32 are added to the configuration. The third postamplifier 31 is connected in parallel with the first postamplifier 21. The fourth postamplifier 32 is connected in parallel with the second postamplifier 22. Other configurations of the amplifier module 1f are the same as or similar to those of the amplifier module 1c described with reference to FIG. 3.

### Operation

The amplifier module 1f has a low power mode and a high power mode as the operation modes having different output power. The high power mode has higher output power than the low power mode. In the low power mode, the first and second postamplifiers 21 and 22 operate, and the third and fourth postamplifiers 31 and 32 do not operate. In the high power mode, the first and second postamplifiers 21 and 22 operate, and the third and fourth postamplifiers 31 and 32 also operate.

As described above, the amplifier module 1f achieves two operation modes. In each of the two operation modes, adjusting the capacitance value of the variable capacitor VC3 enables proper setting of the impedance for each operation mode. For example, the capacitance value of the variable capacitor VC3 is set larger in the low power mode, and the capacitance value of the variable capacitor VC3 is set smaller in the high power mode. In other words, the capacitance value of the variable capacitor VC3 is adjusted so that the capacitance value in the low power mode is higher than the capacitance value in the high power mode. In this case, the impedance may more properly be adjusted not solely with the variable capacitor VC3 but with an LC circuit including the wire traces L21 and L22 in addition to the variable capacitor VC3.

### Seventh Embodiment

### Configuration

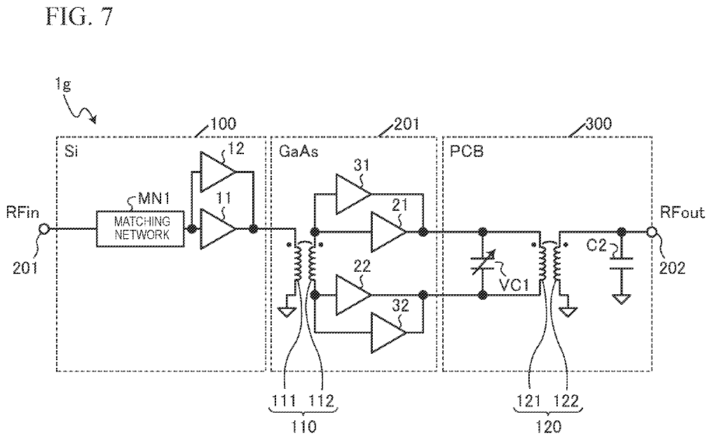

FIG. 7 depicts an example of an amplifier module according to a seventh embodiment of the present disclosure. An amplifier module 1g depicted in FIG. 7 has the same configuration as the amplifier module 1d described with reference to FIG. 4 except that a second preamplifier 12 is added to the configuration. The preamplifier 12 is disposed in or on the silicon (Si) substrate 100, which is the first substrate, together with the first preamplifier 11 and the first matching network MN1.

The second preamplifier 12 is disposed in parallel with the first preamplifier 11. The amplifier module 1g is configured to switch between operation using the first preamplifier 11 and operation using the second preamplifier 12. For example, the first preamplifier 11 is configured to operate in a low power mode described below. The second preamplifier 12 is configured to operate in a high power mode described below.

### Operation

The amplifier module 1g has the low power mode and the high power mode as the operation modes having different output power. The high power mode has higher output power than the low power mode.

In the low power mode of the amplifier module 1g, the first preamplifier 11, the first postamplifier 21, and the second postamplifier 22 operate, and the second preamplifier 12, the third postamplifier 31, and the fourth postamplifier 32 do not operate. In the high power mode of the amplifier module 1g, the second preamplifier 12, the first postamplifier 21, the second postamplifier 22, the third postamplifier 31, and the fourth postamplifier 32 operate, and the first preamplifier 11 does not operate.

As described above, the amplifier module 1g achieves two operation modes. In each of the two operation modes, adjusting the capacitance value of the variable capacitor VC1 enables proper setting of the impedance for each operation mode. For example, the capacitance value of the variable capacitor VC1 is set larger in the low power mode, and the capacitance value of the variable capacitor VC1 is set smaller in the high power mode. In other words, the capacitance value of the variable capacitor VC1 is adjusted so that the capacitance value in the low power mode is higher than the capacitance value in the high power mode.

### Eighth Embodiment

### Configuration

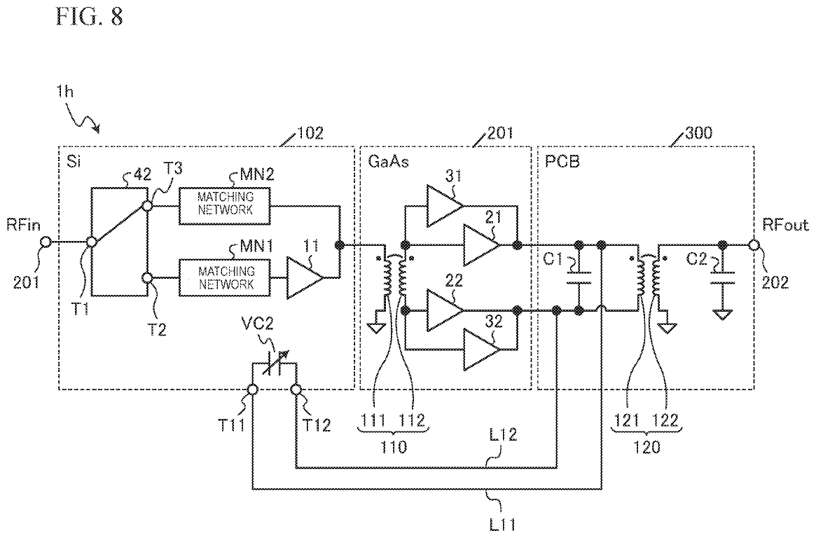

FIG. 8 depicts an example of an amplifier module according to an eighth embodiment of the present disclosure. An amplifier module 1h depicted in FIG. 8 has the same configuration as the amplifier module 1e described with reference to FIG. 5 except that a selector switch 42 and a matching network MN2 are added to the configuration. The selector switch 42, the matching network MN1, the matching network MN2, and the first preamplifier 11 are disposed in or on a silicon (Si) substrate 102, which is a first substrate. Other configurations of the amplifier module 1h are the same as or similar to those of the amplifier module 1e described with reference to FIG. 5.

The selector switch 42 includes terminals T1, T2, and T3. The selector switch 42 is configured to switch between a state for connecting the terminal T1 to the terminal T2 and a state for connecting the terminal T1 to the terminal T3 in response to a control signal not depicted. The selector switch 42 is configured to switch between the connection states based on the operation mode.

The selector switch 42 is configured to provide an operation mode in which the matching network MN1 and the first preamplifier 11 are caused to pass the input signal RFin and an operation mode in which the matching network MN2 is caused to pass the input signal RFin.

The selector switch 42 is configured to cause the matching network MN1 and the first preamplifier 11 to pass the input signal RFin, for example, in a middle power mode and a high power mode, which will be described below. The selector switch 42 is configured to cause the matching network MN2 to pass the input signal RFin in a low power mode. The input signal RFin does not pass through the first preamplifier 11 in the low power mode.

### Operation

The amplifier module 1h has the low power mode, the middle power mode, and the high power mode as the operation modes having different output power. The high power mode has higher output power than the low power mode. The middle power mode has higher output power than the low power mode and has lower output power than the high power mode.

In the low power mode of the amplifier module 1h, the matching network MN2 is caused to pass the input signal RFin, the first postamplifier 21 and the second postamplifier 22 operate, and the third postamplifier 31 and the fourth postamplifier 32 do not operate. In the low power mode, the first postamplifier 21 and the second postamplifier 22 amplify the input signal RFin. In the middle power mode of the amplifier module 1h, after the matching network MN1 and the first preamplifier 11 pass and amplify the input signal RFin, the first postamplifier 21 and the second postamplifier 22 amplify the input signal RFin. In the high power mode of the amplifier module 1h, after the matching network MN1 and the first preamplifier 11 pass and amplify the input signal RFin, the first postamplifier 21, the second postamplifier 22, the third postamplifier 31, and the fourth postamplifier 32 amplify the input signal RFin.

As described above, the amplifier module 1h achieves three operation modes. In each of the three operation modes, adjusting the capacitance value of the variable capacitor VC2 enables proper setting of the impedance for each operation mode. For example, the capacitance value of the variable capacitor VC2 is set larger in the low power mode, and the capacitance value of the variable capacitor VC2 is set smaller in the high power mode. The capacitance value in the middle power mode is set between the capacitance value in the low power mode and the capacitance value in the high power mode. In other words, the capacitance value of the variable capacitor VC2 is adjusted so that the capacitance value in the middle power mode is higher than the capacitance value in the high power mode and the capacitance value in the low power mode is higher than the capacitance value in the middle power mode.

Specifically, the impedance may be adjusted not solely with the variable capacitor VC2 but with an LC circuit including the wire traces L11 and L12 in addition to the variable capacitor VC2.

### Ninth Embodiment

### Configuration

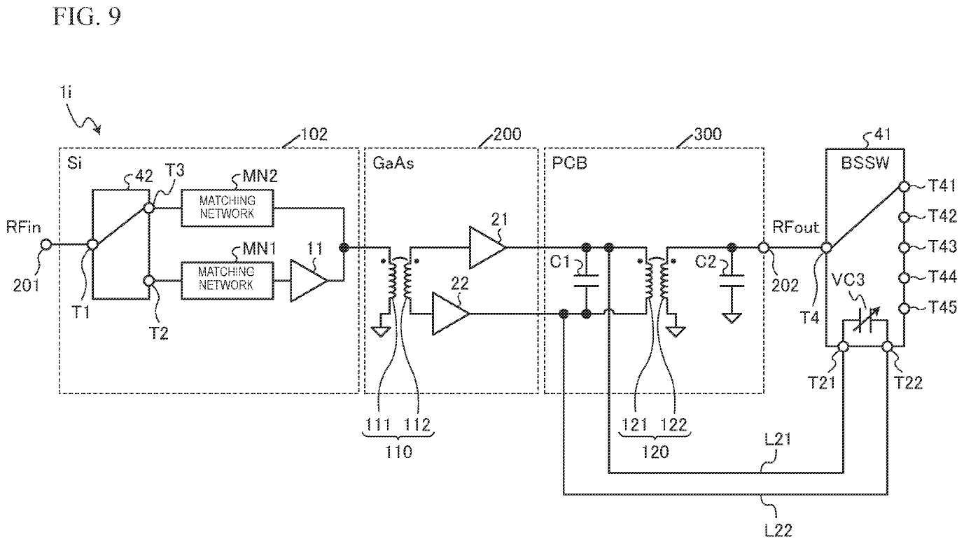

FIG. 9 depicts an example of an amplifier module according to a ninth embodiment of the present disclosure. An amplifier module 1i depicted in FIG. 9 has the same configuration as the amplifier module 1c described with reference to FIG. 3 except that the selector switch 42 and the matching network MN2 are added to the configuration. The selector switch 42, the matching network MN1, the matching network MN2, and the first preamplifier 11 are disposed in or on the silicon (Si) substrate 102, which is the first substrate. Other configurations of the amplifier module 1i are the same as or similar to those of the amplifier module 1c described with reference to FIG. 3.

As described with reference to FIG. 8, the selector switch 42 is configured to switch between the connection states based on the operation mode. The selector switch 42 is configured to provide an operation mode in which the matching network MN1 and the first preamplifier 11 are caused to pass the input signal RFin and an operation mode in which the matching network MN2 is caused to pass the input signal RFin. The selector switch 42 is configured to cause the matching network MN1 and the first preamplifier 11 to pass the input signal RFin, for example, in a high power mode, which will be described below. The selector switch 42 is configured to cause the matching network MN2 to pass the input signal RFin in a low power mode. The input signal RFin does not pass through the first preamplifier 11 in the low power mode.

### Operation

The amplifier module 1i has the low power mode and the high power mode as the operation modes having different output power. The high power mode has higher output power than the low power mode.

In the low power mode of the amplifier module 1i, after the matching network MN2 passes the input signal RFin, the first postamplifier 21 and the second postamplifier 22 amplify the input signal RFin. In the high power mode of the amplifier module 1i, after the matching network MN1 and the first preamplifier 11 pass and amplify the input signal RFin, the first postamplifier 21 and the second postamplifier 22 amplify the input signal RFin.

As described above, the amplifier module 1i achieves two operation modes. In each of the two operation modes, adjusting the capacitance value of the variable capacitor VC3 enables proper setting of the impedance for each operation mode. For example, the capacitance value of the variable capacitor VC3 is set larger in the low power mode, and the capacitance value of the variable capacitor VC3 is set smaller in the high power mode. In other words, the capacitance value of the variable capacitor VC3 is adjusted so that the capacitance value in the low power mode is higher than the capacitance value in the high power mode. The wire traces L11 and L12 each has an inductance value. The impedance may be adjusted not solely with the variable capacitor VC3 but with an LC circuit including the wire traces L21 and L22 in addition to the variable capacitor VC3.

### Tenth Embodiment

### Configuration

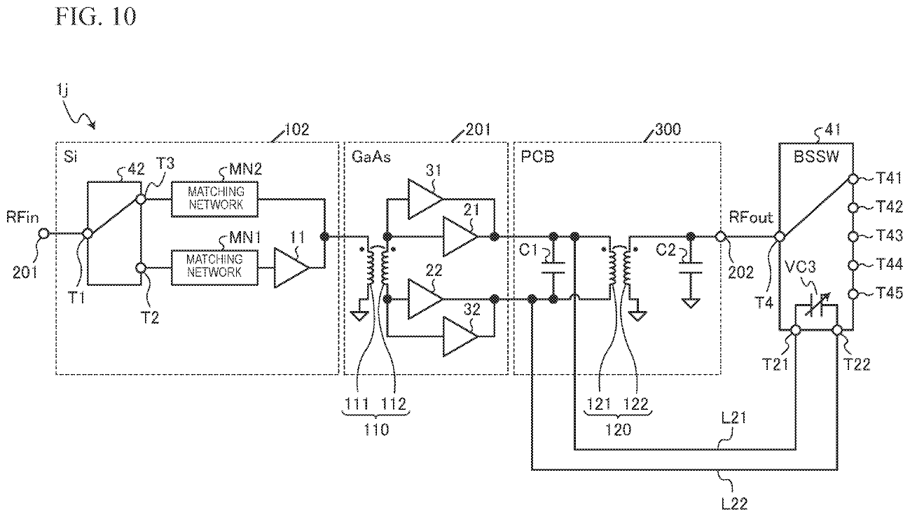

FIG. 10 depicts an example of an amplifier module according to a tenth embodiment of the present disclosure. An amplifier module 1j depicted in FIG. 10 has the same configuration as the amplifier module 1f described with reference to FIG. 6 except that the selector switch 42 and the matching network MN2 are added to the configuration. The selector switch 42, the matching network MN1, the matching network MN2, and the first preamplifier 11 are disposed in or on the silicon (Si) substrate 102, which is the first substrate. Other configurations of the amplifier module 1j are the same as or similar to those of the amplifier module 1f described with reference to FIG. 6.

As described with reference to FIG. 8, the selector switch 42 is configured to switch between the connection states based on the operation mode. The selector switch 42 is configured to provide an operation mode in which the matching network MN1 and the first preamplifier 11 are caused to pass the input signal RFin and an operation mode in which the matching network MN2 is caused to pass the input signal RFin. The selector switch 42 is configured to cause the matching network MN1 and the first preamplifier 11 to pass the input signal RFin, for example, in a middle power mode and a high power mode, which will be described below. The selector switch 42 is configured to cause the matching network MN2 to pass the input signal RFin in a low power mode. The input signal RFin does not pass through the first preamplifier 11 in the low power mode.

### Operation

The amplifier module 1j has the low power mode, the middle power mode, and the high power mode as the operation modes having different output power. The high power mode has higher output power than the low power mode. The middle power mode has higher output power than the low power mode and has lower output power than the high power mode.

In the low power mode of the amplifier module 1j, the matching network MN2 is caused to pass the input signal RFin, the first postamplifier 21 and the second postamplifier 22 operate, and the third postamplifier 31 and the fourth postamplifier 32 do not operate. In the low power mode, the first postamplifier 21 and the second postamplifier 22 amplify the input signal RFin. In the middle power mode of the amplifier module 1j, after the matching network MN1 and the first preamplifier 11 pass and amplify the input signal RFin, the first postamplifier 21 and the second postamplifier 22 amplify the input signal RFin. In the high power mode of the amplifier module 1j, after the matching network MN1 and the first preamplifier 11 pass and amplify the input signal RFin, the first postamplifier 21, the second postamplifier 22, the third postamplifier 31, and the fourth postamplifier 32 amplify the input signal RFin.

As described above, the amplifier module 1j achieves three operation modes. In each of the three operation modes, adjusting the capacitance value of the variable capacitor VC3 enables proper setting of the impedance for each operation mode. For example, the capacitance value of the variable capacitor VC3 is set larger in the low power mode, and the capacitance value of the variable capacitor VC3 is set smaller in the high power mode. The capacitance value in the middle power mode is set between the capacitance value in the low power mode and the capacitance value in the high power mode. In other words, the capacitance value of the variable capacitor VC3 is adjusted so that the capacitance value in the middle power mode is higher than the capacitance value in the high power mode and the capacitance value in the low power mode is higher than the capacitance value in the middle power mode. The wire traces L21 and L22 each has an inductance value. The impedance may be adjusted not solely with the variable capacitor VC3 but with an LC circuit including the wire traces L21 and L22 in addition to the variable capacitor VC3.

### Effect of Capacitance Value Adjustment

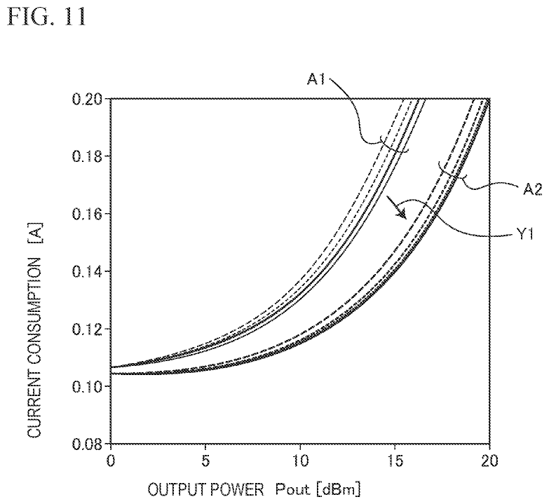

FIG. 11 illustrates an effect of capacitance value adjustment. In FIG. 11, the horizontal axis represents output power Pout [dBm], and the vertical axis represents current consumption [A]. FIG. 11 depicts the current consumption in low power modes as functions of the output power Pout.

As depicted in FIG. 11, the current consumption in the low power modes may be reduced by an increase in the capacitance value. Specifically, as indicated by an arrow Y1 in FIG. 11, characteristics A1 before capacitance adjustment may be changed to characteristics A2 after capacitance adjustment. As can be seen, the characteristics A2 represent lower power consumption than the characteristics A1. In summary, as described with reference to FIGS. 1 to 10, capacitance value adjustment depending on the power mode and an optimal setting of the impedance may lead to a reduction in the current consumption.

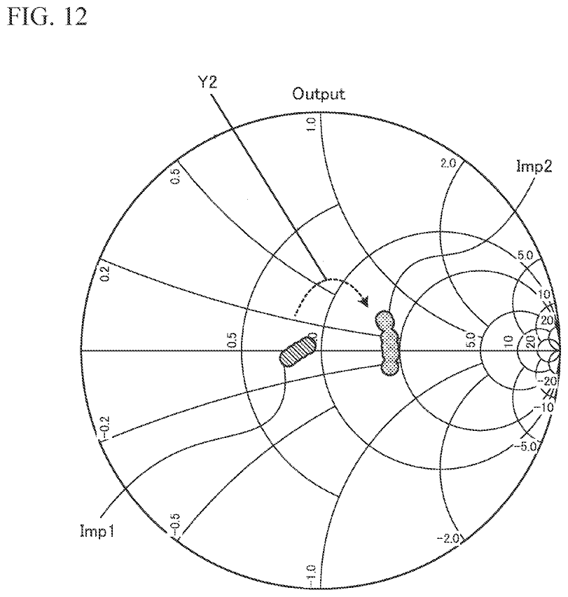

FIG. 12 is a Smith chart illustrating a relationship between impedance adjustment and current consumption. In FIG. 12, impedance Imp1 before capacitance adjustment and impedance Imp2 after capacitance adjustment are plotted. As indicated by an arrow Y2 in FIG. 12, the change from the impedance Imp1 before capacitance adjustment to the impedance Imp2 after capacitance adjustment may lead to a reduction in the current consumption. In other words, adjusting the capacitance to increase the load impedance of a transistor may lead to a reduction in the current consumption.

### Example of Layout

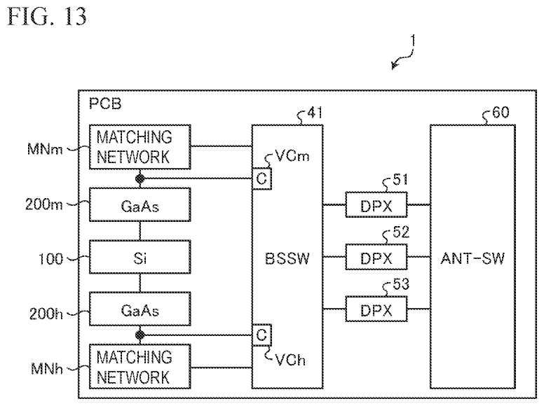

FIG. 13 depicts an example of the layout of an amplifier module. FIG. 13 schematically depicts the layout of an amplifier module. An amplifier module 1 depicted in FIG. 13 includes a silicon substrate 100, a gallium arsenide (GaAs) substrate 200m for a middle band, a gallium arsenide (GaAs) substrate 200h for a high band, a matching network MNm for the middle band, a matching network MNh for the high band, a band select switch (BSSW) 41, duplexers (DPXs) 51, 52, and 53, and an antenna select switch (ANT-SW) 60. These components are disposed on a printed circuit board.

One or more preamplifiers corresponding to a driver stage are disposed in or on the silicon substrate 100. One or more postamplifiers corresponding to a power stage are disposed in or on the gallium arsenide substrate 200m or 200h. A different postamplifier is disposed for each frequency range of a signal to be amplified. For example, a postamplifier configured to amplify a signal in a frequency range included in the middle band is disposed in or on the gallium arsenide substrate 200m, and a postamplifier configured to amplify a signal in a frequency range included in the high band is disposed in or on the gallium arsenide substrate 200h. The output end of the gallium arsenide substrate 200m is connected to the band select switch 41 via the matching network MNm. The output end of the gallium arsenide substrate 200h is connected to the band select switch 41 via the matching network MNh. The matching network MNm and the matching network MNh are disposed on a printed circuit board (PCB) and each includes the inductors 121 and 122 and the capacitors C1 and C2 or the variable capacitors VC1 and VC2.

The band select switch 41 is connected to the duplexers (DPXs) 51, 52, and 53. Different frequencies are assigned to transmission and reception for the duplexers 51, 52, and 53. Specifically, each of the duplexers 51, 52, and 53 includes a transmit filter and a receive filter, and, for example, each transmit filter is connected to the band select switch 41 and each receive filter is connected to another band select switch (not depicted). A duplexer (DPX) is formed of, for example, a surface acoustic wave (SAW) filter made of ceramics. The duplexers 51, 52, and 53 are connected to the antenna select switch (ANT-SW) 60.

The band select switch 41 includes a variable capacitor VCm for the middle band and the variable capacitor VCh for the high band. The variable capacitor VCm is electrically connected to the gallium arsenide substrate 200m via wire traces. The variable capacitor VCh is electrically connected to the gallium arsenide substrate 200h via wire traces. As described above, the variable capacitor VCm and the variable capacitor VCh enable proper adjustment of the impedance value.

The present disclosure may include the following aspects in accordance with the description in the claims.

(1)

An amplifier module comprising:
an input terminal;
a first preamplifier formed in or on a first substrate and configured to amplify a signal that is input to the input terminal;
a first postamplifier and a second postamplifier that are formed in or on a second substrate and that are configured to receive an output of the first preamplifier and output a differential signal;
an output balun configured to receive the differential signal that is output from the first postamplifier and the second postamplifier; and
a variable capacitance element,
wherein the output balun includes a primary winding subjected to the differential signal and a secondary winding, and
the variable capacitance element is connected in parallel with the primary winding of the output balun.
   (2)

The amplifier module according to (1)
wherein the first substrate is made of silicon, and
the second substrate is made of gallium arsenide.
   (3)

The amplifier module according to (1) or (2),
wherein the output balun is disposed in or on a substrate different from a substrate where the variable capacitance element is disposed.
   (4)

The amplifier module according to any one of (1) to (3), further comprising:
a fixed capacitance element connected in parallel with the primary winding of the output balun,
wherein the variable capacitance element is connected in parallel with the fixed capacitance element,
the variable capacitance element is disposed in or on the first substrate, and
the variable capacitance element is electrically connected to the primary winding of the output balun using a wire trace.
   (5)

The amplifier module according to any one of (1) to (3), further comprising:
a fixed capacitance element connected in parallel with the primary winding of the output balun; and
a band select switch unit connected to the secondary winding of the output balun,
wherein the variable capacitance element is connected in parallel with the fixed capacitance element,
the variable capacitance element is disposed in or on a substrate where the band select switch unit is disposed, and
the variable capacitance element is electrically connected to the primary winding of the output balun using a wire trace.
   (6)

The amplifier module according to (4) or (5),
wherein a capacitance value of the variable capacitance element is allowed to vary from a minimum value to a maximum value, and
the maximum value of the variable capacitance element is less than a capacitance value of the fixed capacitance element.
   (7)

The amplifier module according to any one of (1) to (6), further comprising:
a third postamplifier disposed in parallel with the first postamplifier; and
a fourth postamplifier disposed in parallel with the second postamplifier,
wherein the amplifier module is configured to switch between operation in a first operation mode in which the first and second postamplifiers operate and operation in a second operation mode in which the third and fourth postamplifiers operate.
   (8)

The amplifier module according to any one of (1) to (7), further comprising:
a second preamplifier disposed in parallel with the first preamplifier,
wherein the amplifier module is configured to switch between operation using the first preamplifier and operation using the second preamplifier.

What is claimed is:

1. An amplifier module comprising:
an input terminal;
a first preamplifier that is in or on a first substrate, and that is configured to amplify a signal that is input to the input terminal;
a first postamplifier and a second postamplifier that are in or on a second substrate, and that are configured to receive an output of the first preamplifier and to output a differential signal;
an output balun configured to receive the differential signal that is output from the first postamplifier and the second postamplifier; and
a variable capacitance element,
wherein the output balun comprises a primary winding subjected to the differential signal, and a secondary winding, and
wherein the variable capacitance element is connected in parallel with the primary winding of the output balun.

2. The amplifier module according to claim 1,
wherein the first substrate is made of silicon, and
wherein the second substrate is made of gallium arsenide.

3. The amplifier module according to claim 1, wherein the output balun is in or on a different substrate different than the variable capacitance element.

4. The amplifier module according to claim 2, wherein the output balun is in or on a different substrate different than the variable capacitance element.

5. The amplifier module according to claim 1, further comprising:
a fixed capacitance element connected in parallel with the primary winding of the output balun,
wherein the variable capacitance element is electrically connected in parallel with the fixed capacitance element,
wherein the variable capacitance element is in or on the first substrate, and
wherein the variable capacitance element is electrically connected to the primary winding of the output balun by a wire trace.

6. The amplifier module according to claim 2, further comprising:
a fixed capacitance element connected in parallel with the primary winding of the output balun,
wherein the variable capacitance element is electrically connected in parallel with the fixed capacitance element,
wherein the variable capacitance element is in or on the first substrate, and
wherein the variable capacitance element is electrically connected to the primary winding of the output balun by a wire trace.

7. The amplifier module according to claim 1, further comprising:
a fixed capacitance element electrically connected in parallel with the primary winding of the output balun; and
a band select switch connected to the secondary winding of the output balun,
wherein the variable capacitance element is electrically connected in parallel with the fixed capacitance element,
wherein the variable capacitance element is in or on a same substrate as the band select switch, and
wherein the variable capacitance element is electrically connected to the primary winding of the output balun by a wire trace.

8. The amplifier module according to claim 2, further comprising:
a fixed capacitance element electrically connected in parallel with the primary winding of the output balun; and
a band select switch connected to the secondary winding of the output balun,
wherein the variable capacitance element is electrically connected in parallel with the fixed capacitance element,
wherein the variable capacitance element is in or on a same substrate as the band select switch, and
wherein the variable capacitance element is electrically connected to the primary winding of the output balun by a wire trace.

9. The amplifier module according to claim 5,
wherein a capacitance value of the variable capacitance element is configured to vary from a minimum value to a maximum value, and
wherein the maximum value of the variable capacitance element is less than a capacitance value of the fixed capacitance element.

10. The amplifier module according to claim 6,
wherein a capacitance value of the variable capacitance element is configured to vary from a minimum value to a maximum value, and
wherein the maximum value of the variable capacitance element is less than a capacitance value of the fixed capacitance element.

11. The amplifier module according to claim 1, further comprising:
a third postamplifier electrically connected in parallel with the first postamplifier; and
a fourth postamplifier electrically connected in parallel with the second postamplifier,
wherein the amplifier module is configured to switch between operation in a first operation mode in which the first and second postamplifiers operate, and operation in a second operation mode in which the third and fourth postamplifiers operate.

12. The amplifier module according to claim 2, further comprising:
a third postamplifier electrically connected in parallel with the first postamplifier; and
a fourth postamplifier electrically connected in parallel with the second postamplifier,
wherein the amplifier module is configured to switch between operation in a first operation mode in which the first and second postamplifiers operate, and operation in a second operation mode in which the third and fourth postamplifiers operate.

13. The amplifier module according to claim 1, further comprising:
a second preamplifier electrically connected in parallel with the first preamplifier,
wherein the amplifier module is configured to switch between operation using the first preamplifier and operation using the second preamplifier.

14. The amplifier module according to claim 2, further comprising:
a second preamplifier electrically connected in parallel with the first preamplifier,
wherein the amplifier module is configured to switch between operation using the first preamplifier and operation using the second preamplifier.
